(19) United States
(12) Patent Application Publication
(10) Pub. No.: US 2011/0057220 A1
(43) Pub. Date: Mar. 10, 2011

(54) NITRIDE SEMICONDUCTOR LIGHT-EMITTING DEVICE

(76) Inventors: Atsunori MOCHIDA, Hyogo (JP); Kouji MAKITA, Hyogo (JP); Yoshiaki HASEGAWA, Okayama (JP)

(21) Appl. No.: 12/790,247

(22) Filed: May 28, 2010

(30) Foreign Application Priority Data
Sep. 9, 2009 (JP) 2009-207764

(51) Int. Cl. H01L 33/46

(52) U.S. Cl. 257/98; 257/E33.068

(57) ABSTRACT

A nitride semiconductor light-emitting device includes a laminate structure formed of a plurality of nitride semiconductor layers including a light-emitting layer, and having cavity facets facing each other, a first protection film made of AlN, formed over a light-emitting facet of the cavity facets, and a second protection film made of Al₂O₃ having a refractive index of n1, formed thereon. The second protection film has a crystallized surface at least in a region facing a light-emitting region on the cavity facets; the thickness (t) of the second protection film satisfies λ/(2·n1)<t<3λ/(4·n1) (where λ is a wavelength of the output light); and a second reflectance R(n2) (where n2 is a refractive index of crystallized Al₂O₃) of the light-emitting region in the cavity facets is lower than a first reflectance R(n1) of a region surrounding the light-emitting region in the cavity facets.

### CROSS-REFERENCE TO RELATED APPLICATION

This application claims priority to Japanese Patent Application No. 2009-207764 filed on Sep. 9, 2009, the disclosure of which including the specification, the drawings, and the claims is hereby incorporated by reference in its entirety.

### BACKGROUND

The present disclosure relates to nitride semiconductor light-emitting devices, and more particularly to nitride semiconductor light-emitting devices having facet protection films.

Nowadays, various semiconductor laser diodes are broadly used as light sources for optical disk devices. Among others, a blue-violet semiconductor laser diode using a III-V nitride semiconductor, such as gallium nitride (GaN), emits light in a short-wavelength region (400 nm band), which enables a smaller size of light collection spot on an optical disk as compared with light in a red region and in an infra-red region, as a light source for the next-generation high-density optical disk (Blu-ray Disc (registered trademark)). This is advantageous for improvement in playback operation and record density of optical disks, and thus blue-violet semiconductor laser diodes are becoming commonplace as well as indispensable.

In order to achieve high density and high-speed write operation, a novel disk utilizing a blue-violet semiconductor laser diode requires a high-power blue-violet semiconductor laser diode with high reliability. In an aluminum gallium arsenide (AlGaAs)-based semiconductor laser diode or an aluminum gallium indium phosphide (AlGaInP)-based semiconductor laser diode used in a conventional CD (compact disc) and DVD (digital versatile disc), dielectric films made of oxide are formed over cavity facets as protection films in order to prevent degradation and optical damage of the cavity facets.

However, in case of a GaN-based blue-violet laser diode, if a facet protection film made of oxide is formed over a cavity facet, then the cavity facet is oxidized by oxygen in the facet protection film as well as oxygen in the air. This causes facet degradation of a semiconductor laser diode.

Thus, an attempt to shield the cavity facets from oxygen to reduce degradation thereof caused by oxidation of the facets by providing a layer made of aluminum nitride (AlN) over a facet protection film is described, for example, in Japanese Patent Publication No. 2007-103814 etc.

In addition, for example, Japanese Patent Publication No. 2008-186837 etc. describe an attempt to prevent increase of drive current (Top) of a laser diode by exploiting a fact that if a facet protection film is formed of a first film made of aluminum nitride (AlN) and a second film made of aluminum oxide (Al₂O₃), and if the film thickness “d” of the second film satisfies R(d, n)>R(d, n+1) and d>λ/n (where R is the reflectance, n is the refractive index, and λ is the light wavelength), then the refractive index of the second film increases and the reflectance thereof decreases due to change in properties of the second film during laser operation.

### SUMMARY

However, high-power operation with an optical output of 160 mW or higher, which is applied to, for example, Blu-ray Disc on which dual layer recording can be performed at 4× or faster, cannot be stably achieved only with the configuration described above.

Generally, facet degradation causes an increase of operating current and a decrease of COD (catastrophic optical damage) optical output which results in COD, thereby hinders high-power operation. For this reason, it is known that continued high-power operation will cause operating current to be gradually increased, or to be rapidly increased to stop the light emission. Thus, the present inventors have conducted various studies, focusing on oxidation of a boundary between a cavity facet and an aluminum nitride (AlN) film and light absorption by the aluminum nitride film. As a result, it has been found that forming a facet protection film by a thin aluminum nitride film having an orientation where the crystal axis is different by 90° from the cavity facet is effective in reducing facet degradation because light absorption by the facet protection film can be reduced and oxidation toward the cavity facet can be reduced.

In addition, in case of a configuration in which an aluminum oxide (Al₂O₃) film is provided over a cavity facet interposing an aluminum nitride film therebetween, it has been found that it is also required to take into consideration an effect of oxygen permeability of an aluminum oxide film and stress thereof on a boundary between a cavity facet and an aluminum nitride film. That is, from a viewpoint of stress, aluminum oxide, which has relatively small stress, is suitable for a facet-coating film. However, since aluminum oxide has a low crystallization temperature to crystallize from an amorphous state, a change in properties readily occurs on boundaries with, and on surfaces of, semiconductor crystals (a region with changed properties is referred to hereinafter as “crystallized region”) if high-energy blue-violet laser light is emitted for a long period of time. As such, in a semiconductor laser diode, continued high-power operation causes the properties of an aluminum oxide film, which serves as a facet-coating film, to change from the surface, and thus causes the stress and the refractive index thereof to change gradually.

For example, aluminum oxide has a refractive index of 1.66 in an amorphous state, and even though a specific refractive index of a crystallized region is unknown, sapphire, which is a crystallized material, for example, has a refractive index of 1.76. This provides an estimation of a change within a range of approximately 0.1 or less.

In view of the foregoing, it is an object of the present disclosure to provide a facet protection film which reduces an increase of current associated with a decrease of COD optical output over time due to facet degradation during operation and can withstand high-power laser operation over a long period of time.

In order to achieve the above object, a nitride semiconductor light-emitting device includes a laminate structure formed of a plurality of nitride semiconductor layers including a light-emitting layer, and having cavity facets facing each other, a first protection film made of aluminum nitride, formed over a light-emitting facet of the cavity facets, and a second protection film made of aluminum oxide having a refractive index of n1, formed over the first protection film, where the second protection film has a crystallized surface at least in a region facing a light-emitting region on the cavity facets; the thickness (t) of the second protection film satisfies λ/(2·n1)<t<3λ/(4·n1) (where λ is a wavelength of the output light); and a second reflectance R(n2) (where n2 is a refractive index of the aluminum oxide which has been crystallized) of the light-emitting region in the cavity facets is lower than a first reflectance R(n1) of a region surrounding the light-emitting region in the cavity facets.

According to a nitride semiconductor light-emitting device of the present invention, since the first protection film is made of aluminum nitride, the cavity facet is shielded from oxygen. This hinders oxygen permeation during laser operation, and allows reduction of facet degradation. In addition, the second protection film is made of aluminum oxide, the film thickness satisfies λ(2·n1)<t<3λ(4·n1), and the facet reflectances satisfy R(n2)<R(n1). Thus, it is possible to prevent an increase of operating current due to crystallization of the second protection film. This can reduce facet degradation due to increase of operating current during laser operation, and this can also reduce facet degradation associated with increase in stress.

In the nitride semiconductor light-emitting device according to the present invention, the aluminum nitride forming the first protection film may have an orientation where the crystal axis is different by 90° from the optical cavity facets.

With this configuration, the first protection film has a dense film characteristic, thereby further hinders oxygen permeation during laser operation, and thus allows facet degradation in the cavity facet to be further reduced. Accordingly, high-power operation of 160 mW or higher can be stably achieved.

In the nitride semiconductor light-emitting device according to the present invention, the first protection film may have a film thickness of 4 nm or more and 20 nm or less.

This configuration can prevent variation in oxygen permeability of the cavity facet due to variation in the film thickness of the aluminum nitride film. In addition, since the film thickness of the aluminum nitride film of 20 nm or less can reduce the laser light absorption according to the extinction coefficient of the aluminum nitride film, facet degradation during laser operation can be reduced. Moreover, the film thickness of the aluminum nitride film of 4 nm or more can reduce crystallization on the side of the first protection film in the second protection film.

In the nitride semiconductor light-emitting device according to the present invention, the extinction coefficient of the first protection film may be 0.005 or less over a range of oscillation wavelength of the light emitted from the light-emitting layer.

This configuration can reduce light absorption by the first protection film facing the light-emitting region, and thus can further reduce facet degradation in the cavity facet.

In the nitride semiconductor light-emitting device according to the present invention, a reflectance of a facet-coating film formed of the first protection film and the second protection film may be 8% or more and 13% or less.

This configuration can reduce degradation of noise characteristics. In addition, the reflectance of the facet-coating film of 13% or less allows the optical density of an end portion of the light-emitting region to be set to a small value.

The nitride semiconductor light-emitting device according to the present invention may further include a third protection film formed over a light-reflecting facet opposite the light-emitting facet of the cavity facets, and having the same configuration as that of the first protection film, and a fourth protection film formed over the third protection film, and having the same configuration as that of the second protection film.

This configuration can reduce facet degradation due to oxidation of the light-reflecting facet.

As described above, according to a nitride semiconductor light-emitting device of the present invention, since increase of operating current due to crystallization of the protection films made of aluminum oxide can be reduced, and oxidation and stress at the boundary between the cavity facet and the first protection film can be reduced, a facet protection film which can withstand high-power operation for a long period of time can be achieved. As a result, high-power operation of 160 mW or higher, applicable to, for example, Blu-ray Disc on which dual layer recording can be performed at 4× or faster, can be performed.

### BRIEF DESCRIPTION OF THE DRAWINGS

FIG. 1 is a cross-sectional view taken along a perpendicular direction to the longitudinal direction of a cavity, illustrating a nitride semiconductor light-emitting device according to an example embodiment.

FIG. 2 is a schematic cross-sectional view illustrating an ECR sputtering system which can deposit protection films in the nitride semiconductor light-emitting device according to the example embodiment.

FIG. 3A is a partial cross-sectional view of the emitting-facet side taken along a direction parallel to the longitudinal direction of the cavity, illustrating the nitride semiconductor light-emitting device according to the example embodiment.

FIG. 3B is a cross-sectional view taken along a direction parallel to the longitudinal direction of the cavity, illustrating the nitride semiconductor light-emitting device according to the example embodiment.

FIG. 4 is a graph showing a dependency of the deposition rate of a protection film on the partial pressure of nitrogen (N₂) in the nitride semiconductor light-emitting device according to the example embodiment.

FIG. 5 is a graph showing a dependency of the relative intensity noise (RIN) on the reflectance of the front facet.

FIG. 6 is a graph showing a dependency of the COD level on the reflectance of the front facet.

FIG. 7 is a graph showing a dependency of the facet reflectances on the film thickness of the second protection film made of Al₂O₃ in the nitride semiconductor light-emitting device according to the example embodiment.

FIG. 8 is a graph showing a dependency of the facet reflectances on the film thickness of the second protection film made of Al₂O₃ when only a portion 50 nm or less inward from the surface is crystallized in the nitride semiconductor light-emitting device according to the example embodiment.

FIGS. 9A-9E are graphs showing a dependency of the operating-current change rate on the aging time for each film thickness range of the second protection film in the nitride semiconductor light-emitting device according to the example embodiment.

FIG. 10 is a graph showing a correlation between the reflectances in the region 3 before and after crystallization of the second protection film made of Al₂O₃ in the nitride semiconductor light-emitting device according to the example embodiment.

FIG. 11 is a graph showing a dependency of the facet reflectances on the film thickness of the second protection film made of Al₂O₃ when the film thickness of the first protection film made of AlN is 4 nm, in the nitride semiconductor light-emitting device according to the example embodiment.

FIG. 12 is a graph showing a dependency of the facet reflectances on the film thickness of the second protection film made of Al₂O₃ when the film thickness of the first protection film made of AlN is 20 nm, in the nitride semiconductor light-emitting device according to the example embodiment.

FIG. 13 is a graph showing a correlation between the extinction coefficient of the first protection film made of AlN and the amount of decrease of the COD level according to the example embodiment.

### DETAILED DESCRIPTION

### Example Embodiment

An example embodiment will be described below with reference to the drawings.

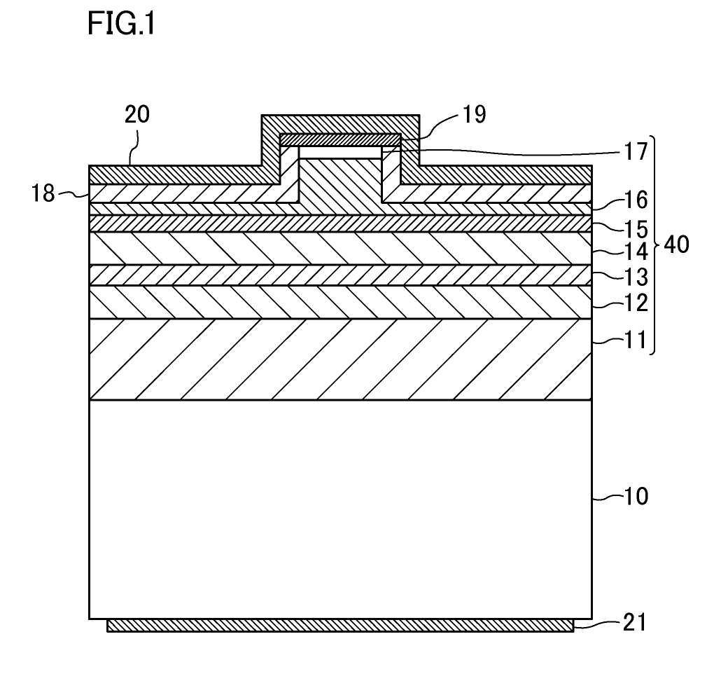

As shown in FIG. 1, a nitride semiconductor light-emitting device according to this embodiment includes an n-type cladding layer 11 made of n-type AlGaN having a thickness of 1.5 μm, an n-type optical guide layer 12 made of n-type GaN having a thickness of 0.016 μm, a multiple-quantum-well active layer 13 made of InGaN having a well-layer thickness of 7 nm and a barrier-layer thickness of 13 nm, an optical guide layer 14 made of InGaN having a thickness of 0.06 μm, a p-type optical guide layer 15 made of p-type AlGaN having a thickness of 0.1 μm, a p-type cladding layer 16 made of p-type AlGaN having a thickness of 0.5 μm, and a p-type contact layer 17 made of p-type GaN having a thickness of 0.1 μm, all of which are sequentially formed over a principal surface of an n-type substrate 10 made of n-type GaN having a thickness of approximately 80 μm. The semiconductor layers from the n-type cladding layer 11 to the p-type contact layer 17 are hereinafter collectively referred to as a laminate structure 40. Note that the film thicknesses of the respective semiconductor layers described above are merely by way of example, and this embodiment is not intended to be limited to this.

In the laminate structure 40, a part of the p-type cladding layer 16 and the p-type contact layer 17 are processed into a ridge-stripe geometry extending along the longitudinal direction of a cavity. The width of the ridge-stripe portion is, for example, about 1.4 μm. The cavity length is, for example, 800 μm. The chip width is, for example, 200 μm.

A p-side contact electrode 19 made of palladium (Pd)/platinum (Pt) is formed over the top surface of the ridge-stripe portion so as to contact the p-type contact layer 17. A dielectric film 18 is formed over the exposed portion of the p-type cladding layer 16 other than the top surface of the ridge-stripe portion. A p-side interconnect electrode 20 made of titanium (Ti)/platinum (Pt)/gold (Au) is formed over the p-side contact electrode 19 in the ridge-stripe portion and the dielectric film 18. In addition, an n-side contact electrode 21 made of Ti/Pt/Au is formed over a surface (rear surface) on the opposite side of the substrate 10 from the laminate structure 40.

A low-reflection front-facet-coating film (not shown) formed of aluminum nitride (AlN) and aluminum oxide (Al₂O₃) films is formed over an emitting facet, which is the front facet of the cavity. In addition, a high-reflection rear-facet-coating film (not shown) formed of an aluminum oxide (Al₂O₃) film and six cycles of silicon dioxide (SiO₂) and zirconium dioxide (ZrO₂) films stacked thereover is formed over a reflecting facet, which is the rear facet of the cavity.

A method for fabricating the nitride semiconductor light-emitting device configured as described above will be described below.

First, the laminate structure 40 constituting the nitride semiconductor light-emitting device is formed on the principal surface of the n-type substrate 10 by crystal growth using a metal-organic chemical vapor deposition (MOCVD) technique.

Next, for example, a mask film made of SiO₂ etc. is formed over the top surface of the laminate structure 40 for use as a mask for forming a ridge-stripe structure using a plasma-enhanced chemical vapor deposition (CVD) technique etc., and the portion of the mask film other than the ridge-stripe portion is etched by lithography and an etching technique using hydrofluoric acid (HF) etc. The ridge-stripe portion is formed by performing etching down to the inside of the p-type cladding layer 16 by, for example, a dry etching apparatus having an ISM (inductively super magnetron) etc. using the mask film remaining on the ridge-stripe portion. Thereafter, the mask film is removed, and then the dielectric film 18 made of, for example, SiO₂ etc. is formed over the entire surface of the laminate structure 40. After this, only the ridge-stripe portion is opened by lithography, and the dielectric film 18 is etched using hydrofluoric acid (HF) etc. This forms the dielectric film 18 as a current-blocking layer. Following this, a metal film made of Pd/Pt, which is to be the p-side contact electrode 19, is formed by a vacuum evaporation technique, and then the p-side contact electrode 19 is formed by removing the metal film other than the portion over the ridge-stripe portion using a lift-off technique. Then, the p-side interconnect electrode 20 is formed over the dielectric film 18 including the p-side contact electrode 19 by a vacuum evaporation technique.

Next, after the rear surface of the n-type substrate 10 is ground to a thickness of about 80 μm, the n-side contact electrode 21 is formed over the ground rear surface by a vacuum evaporation technique. The laminate structure 40 as shown in FIG. 1 can be formed by the processes described above.

After this, a primary cleavage is performed along the (101-0) plane, which is the plane orientation of the n-type substrate 10, by scribing equipment and breaking equipment, etc. Note that, for purposes herein, a negative sign “−” added to a Miller index for a plane orientation expediently represents an inversion of the Miller index integer immediately before the negative sign. In this embodiment, as described previously, a cavity having a length of 800 μm is formed. In this process, the cleavage is performed while a plurality of light-emitting devices in the form of a wafer are protected by placing the plurality of light-emitting devices in the form of a wafer before the cleavage on an adhesive sheet and a protection sheet is also applied by adhesion on the top surfaces of the plurality of light-emitting devices. Accordingly, when the primary cleavage is performed, the cavity facets of the light-emitting devices are exposed to an atmosphere interposed between the adhesive sheet and the protection sheet, and after the primary cleavage is performed, the cavity facets of the light-emitting devices may contact the adhesive sheet etc. Thus, component materials included in the adhesive sheet etc. may adhere to the cavity facets. Among the component materials included in the adhesive sheet etc. is a siloxane-based component, and siloxane contains silicon (Si). Therefore, adhesion of silicon to the cavity facets may have a significant effect on long-term reliability of a GaN-based nitride light-emitting device. Accordingly, in this embodiment, the primary cleavage is performed using an adhesive sheet and a protection sheet which do not contain silicon.

Next, a facet-coating process in which a protection film made of a dielectric film is formed over each cavity facet of a laser bar including the plurality of light-emitting devices obtained by the primary cleavage using an electron cyclotron resonance (ECR) system will be described.

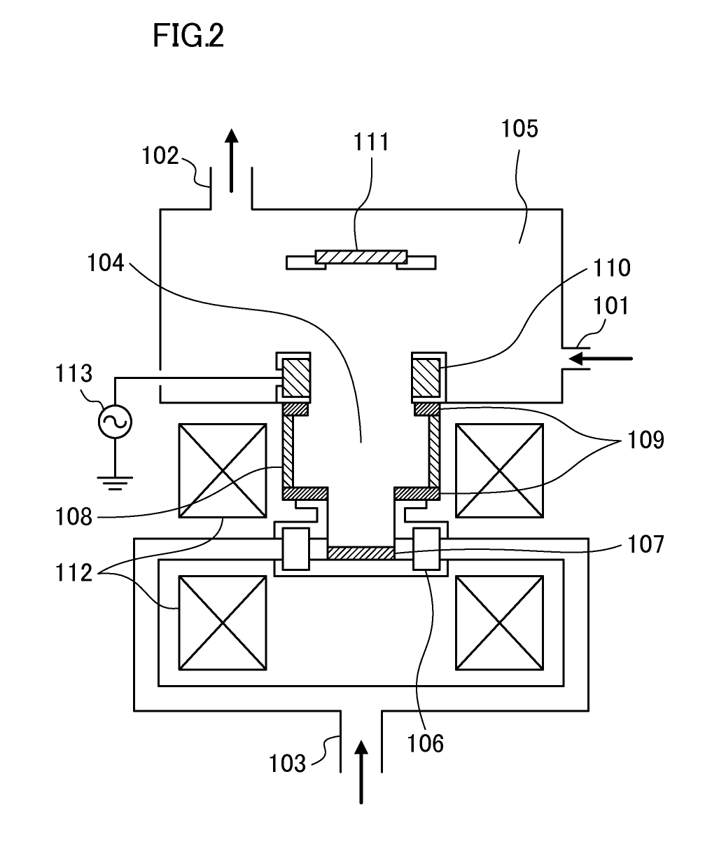

FIG. 2 illustrates a cross-sectional configuration of the ECR system. The ECR system includes a plasma chamber 104 which generates ECR plasma, a film deposition chamber 105 which is coupled to the plasma chamber 104 and where plasma is introduced, target materials 110 held in the film deposition chamber 105, a plurality of magnetic coils 112 which are provided around the plasma chamber 104 and generate a magnetic field. The target materials 110 are connected to a radio-frequency (RF) power source 113, and the amount of sputtering is controlled by the RF power source 113. In this embodiment, high-purity aluminum (Al) is used for the target materials 110.

An inlet window 106 is provided on the opposite side of the plasma chamber 104 from the film deposition chamber 105, and microwave introduced through a microwave inlet 103 is introduced into the plasma chamber 104 through the inlet window 106. ECR plasma is generated in the plasma chamber 104 by the introduced microwave and the magnetic field generated by the magnetic coils 112.

The film deposition chamber 105 is vacuum evacuated through an evacuation outlet 102, while argon (Ar) gas, oxygen (O₂) gas, and nitrogen (N₂) gas are introduced into the film deposition chamber 105 through a gas inlet 101. A stage 111 is disposed at a location facing the plasma chamber 104 in the film deposition chamber 105. A laser bar cleaved by the primary cleavage is introduced into the film deposition chamber 105 and held on the stage 111 so that the cavity facets are exposed to ECR plasma. The inner surface of the plasma chamber 104 is covered by members made of quartz in order to protect the plasma chamber 104 from ECR plasma. That is, an end plate 107, inner tubes 108, and window plates 109 on the top and at the bottom of the respective inner tubes 108 are respectively provided as the quartz members covering the inner surface of the plasma chamber 104.

It is preferable that a cleaning process of the cavity facets be performed before forming facet-coating films, by performing plasma cleaning using Ar gas. In the cleaning process, if only plasma exposure is performed without applying a bias voltage to the target materials 110 in the ECR system, the target materials 110 are not sputtered. That is, the cleaning process can be performed by generating plasma with no bias applied. Note that the cleaning process may be performed using a mixture gas of Ar gas and N₂ gas instead of using only Ar gas.

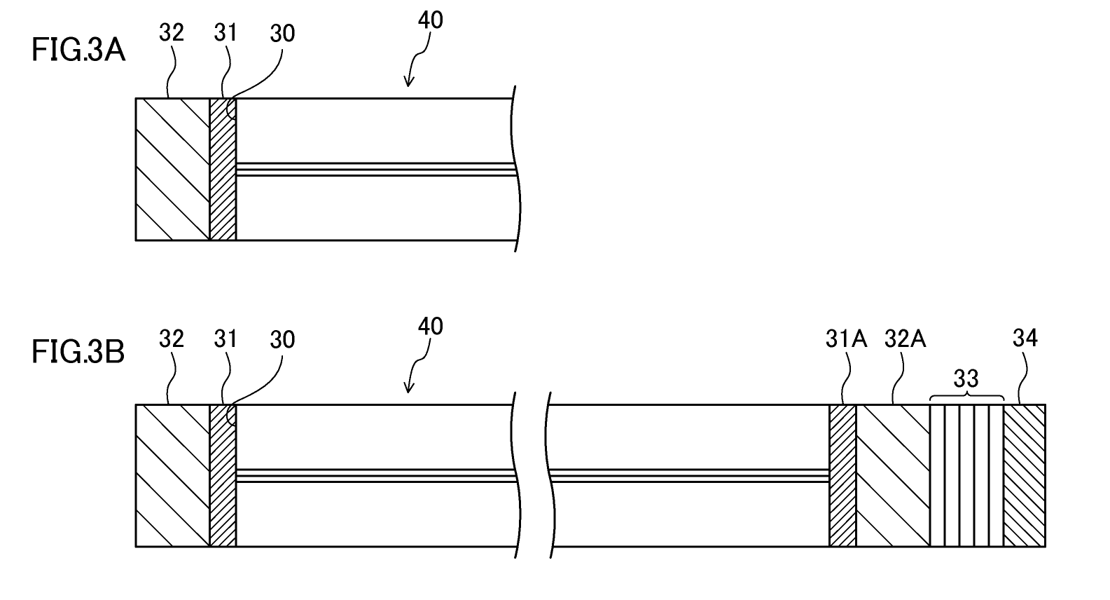

First, the protection film (front-facet-coating film) on the emitting-facet side will be described using FIG. 3A. FIG. 3A illustrates a partial cross-sectional configuration of the emitting-facet side taken along a direction parallel to the longitudinal direction of the cavity. The cleaning process described above is performed before forming the protection film. Then, Ar gas and N₂ gas are introduced to the film deposition chamber 105 to generate plasma, and a predetermined bias voltage is applied to the target materials 110. Thus, an aluminum nitride (AlN) film is deposited as the first protection film 31 on a cavity facet 30 of the laminate structure 40.

Next, after the first protection film 31 has been formed, Ar gas and O₂ gas are introduced to the film deposition chamber 105 where the first protection film 31 has been formed, and an aluminum oxide (Al₂O₃) film is deposited as the second protection film 32 in a similar manner. Note that in this embodiment, the material of the target materials 110 for forming the AlN and the Al₂O₃ films respectively as the first and the second protection films 31 and 32 is aluminum (Al), and thus the films are deposited in an Al target chamber.

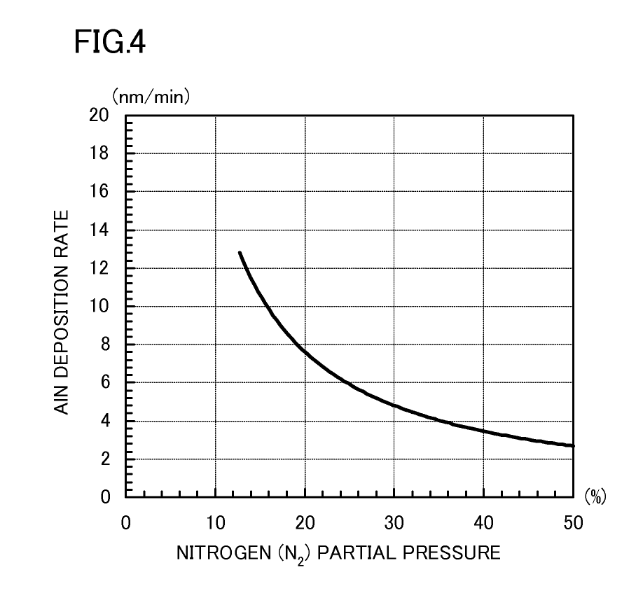

When the AlN film, which is the first protection film 31, is formed, the deposition rate can be reduced by deposition at high partial pressure of nitrogen (N₂) gas as shown in FIG. 4. A reduction in deposition rate causes the state of the crystal axis of the cavity facets to be unlikely to be reflected, and a growth mode with a crystal axis with which the AlN film is easy to grow becomes predominant. This allows a crystalline film having a crystal axis along the c-axis direction (=[0001] direction), which is different by 90° from the cavity facet 30 of the laminate structure 40, to be obtained, and more dense film structure to be achieved. In this way, providing a c-axis oriented AlN crystalline film as the first protection film 31 on the emitting-facet side hinders oxygen permeation to the boundary between the cavity facet 30 and the first protection film 31 during laser operation because the bond distances between constituent atoms are small, and the film quality is dense.

Furthermore, since the deposition condition is such that the N₂ partial pressure is high, that is, the Ar partial pressure is low, plasma damage by the Ar gas in the plasma chamber 104 is reduced, thereby reducing wear caused by etching the quartz members (the end plate 107, the inner tubes 108, and the window plates 109). If the Ar partial pressure is high, this wear occurs when each quartz member is exposed to plasma and the etching process progresses because the mass of Ar is relatively large. As such, since the Ar partial pressure can be set low in this embodiment, the attachment of silicon (Si) and oxygen (O), which are main components of each quartz member, to the boundary between the cavity facet 30 and the first protection film 31 can be reduced. This allows the light absorption of laser light due to a formation of silicon oxides (SiOₓ) at the boundary etc. to be reduced, thereby allows induction of heat generation and degradation of the cavity facet 30 to be reduced.

In this regard, it is preferable that the film thickness of the first protection film 31 made of AlN be set to 4 nm or more and 20 nm or less. The film thickness of the AlN film of 4 nm or more can reduce variation in oxygen permeability of the cavity facet 30 due to variation in the film thickness of the AlN film, and more particularly, can reduce variation in the COD level. In addition, the film thickness of the AlN film of 20 nm or less can reduce the laser light absorption according to the extinction coefficient of the AlN film, and thus can reduce the decrease of the COD level during laser operation as compared to when the film thickness is large. In this embodiment, the film thickness of the first protection film 31 is 10 nm.

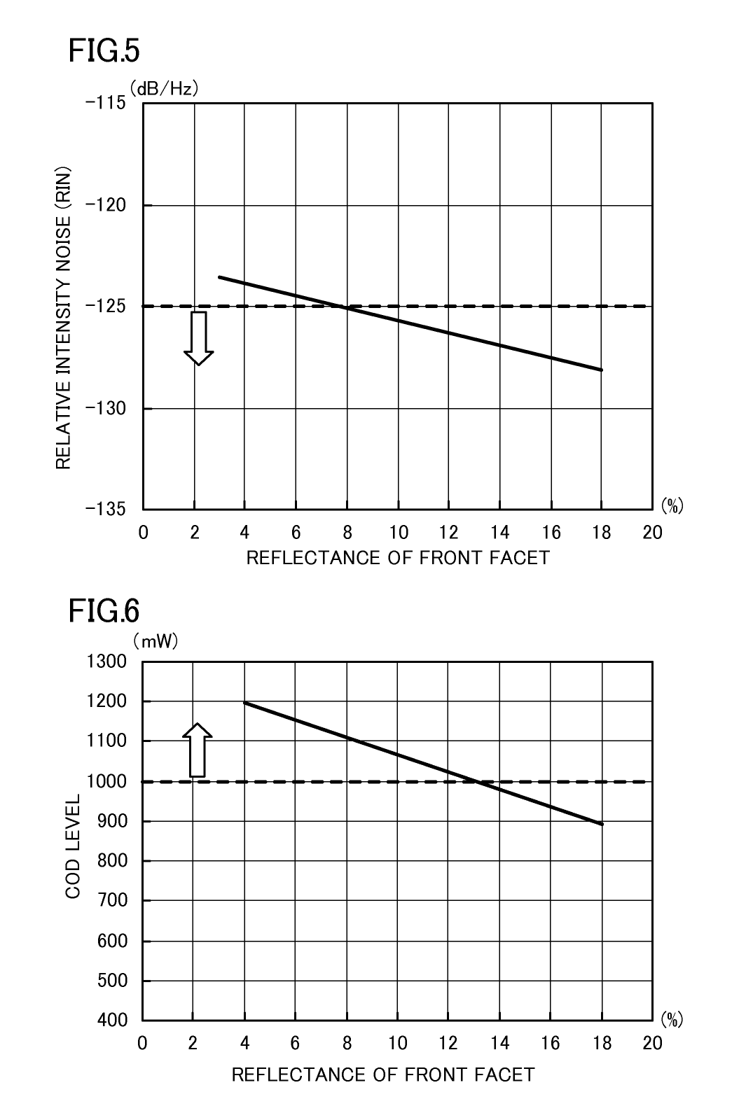

It is preferable that the film thickness of the second protection film 32 made of aluminum oxide (Al₂O₃) be set so that the reflectance at the emitting facet (front facet) is 8% or more and 13% or less. A lower reflectance causes optical feedback noise to occur, which will raise a major issue when this light-emitting device is used in an optical pickup. Although it may not apply depending on the design of a specific optical pickup, it is preferable that the reflectance of the front facet be 8% or more because, from a viewpoint of optical feedback noise, the relative intensity noise (RIN) needs to be −125 dB/Hz or less as shown in FIG. 5. Meanwhile, even though a higher reflectance at the front facet provides more advantages such as a decrease of the threshold current value, optical density of the light-emitting region in the cavity becomes high. Therefore, the COD level at an initial operation stage needs to be set sufficiently high. This is indispensable to achieve high-power operation. That is, as shown in FIG. 6, in order to achieve a COD level of 1000 mW, for example, the facet reflectance is preferably less than or equal to 13%. Accordingly, in this embodiment, the film thickness of the second protection film 32 is 145 nm so that the reflectance in an initial operation stage is 12%.

Here, since blue-violet laser light has high optical energy and the Al₂O₃ forming the second protection film 32 has a low crystallization temperature, a problem exists in that a change in properties occurs due to crystallization of Al₂O₃ particularly at the boundary with the air on or near the outermost surface of the second protection film 32, which is considered to have a high energy level, by prolonged laser-light irradiation. Even though the change in properties due to crystallization of the second protection film 32 is notable especially within a range of oscillation wavelength of blue-violet laser light, there is no limitation on the oscillation wavelength of the light-emitting device because the change in properties occurs independently of the oscillation wavelength. Note that in this embodiment, the oscillation wavelength of the light-emitting device is 405 nm.

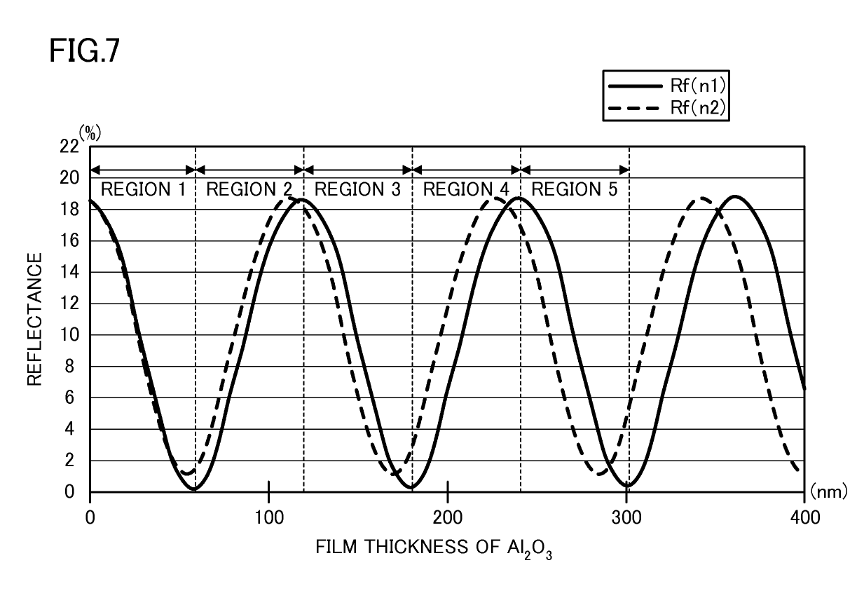

FIG. 7 illustrates a dependency of the reflectances of the cavity facet on the film thickness of the Al₂O₃ film with respect to the AlN forming the first protection film 31 and the Al₂O₃ forming the second protection film 32. Here, the film thickness of the AlN film is 10 nm. In addition, a first facet reflectance associated with a refractive index (n1: e.g., 1.66) before Al₂O₃ is crystallized is denoted by Rf(n1), and a second facet reflectance associated with a refractive index (n2: e.g., 1.76) after Al₂O₃ is completely crystallized in a thickness direction by prolonged laser operation is denoted by Rf(n2).

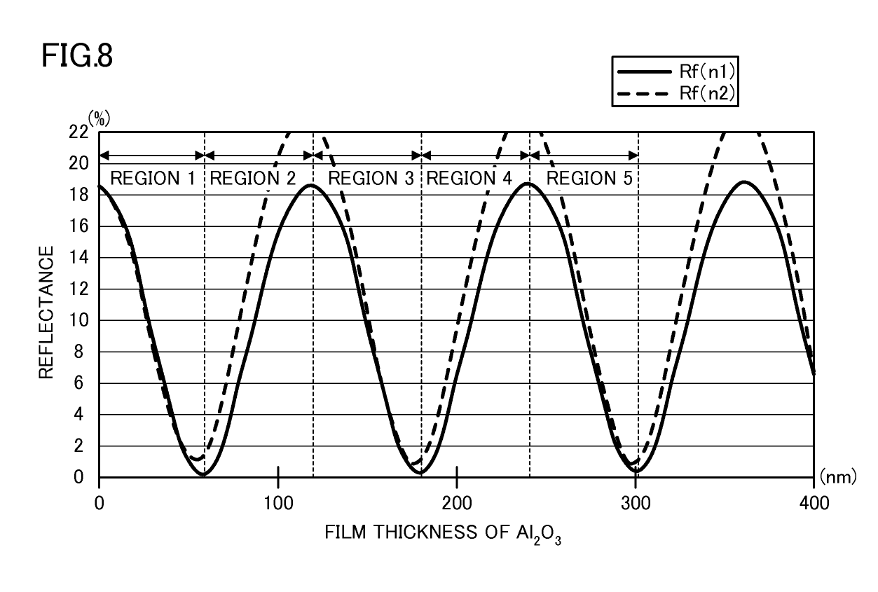

Furthermore, FIG. 8 illustrates a dependency of the reflectances of the cavity facet on the film thickness of the Al₂O₃ film when the Al₂O₃ forming the second protection film 32 is crystallized in a portion 50 nm or less inward from the atmospheric side (outside). The other conditions are similar to those of FIG. 7.

As shown in FIGS. 7 and 8, within the refractive index difference described above, the differential efficiency (Se) decreases and the threshold current value (Ith) also decreases in a region where the reflectance increases due to crystallization of Al₂O₃. On the contrary, in a region where the reflectance decreases, the differential efficiency (Se) increases and the threshold current value (Ith) also increases. In addition, a film thickness value of the Al₂O₃ film also contributes to changing the manners in which the differential efficiency and the threshold current value increase or decrease after prolonged laser operation.

In this embodiment, under a condition of high light-output in which the temperature is 70° C. and the light output is 160 mW of a continuously energized light-emission, change in the differential efficiency (Se) has more effect on the drive current (lop) than change in the threshold current value (Ith). This causes an operating-current change rate (ΔIop) before and after the continuously energized light-emission to increase in a region where the reflectance increases, and to decrease in a region where the reflectance decreases.

In the regions 1-5 of respective film thickness ranges, since crystallization of Al₂O₃ progresses gradually and the facet reflectance changes monotonously, the film thickness of the Al₂O₃ film needs to be set to a value within a region where the reflectance decreases in order to reduce the change in the operating-current change rate (ΔIop) during a continuously energized light-emission. Accordingly, in this embodiment, the film thickness is 145 nm which belongs to the region 3 as shown in FIG. 7.

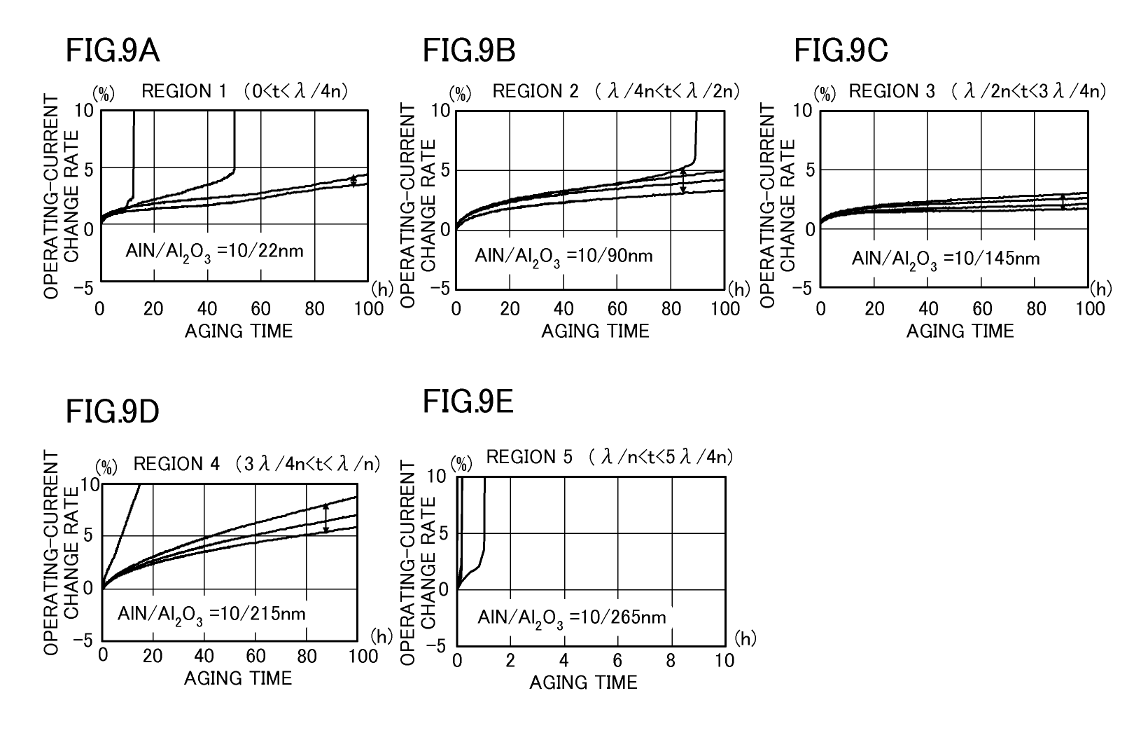

In FIGS. 9A-9E, a dependency of the operating-current change rate (ΔIop) on the aging time under a condition of continuously energized light-emission with the temperature of 70° C. and the light output of 160 mW is illustrated for each of the regions 1-5 where the film thickness of the first protection film 31 made of AlN is 10 nm, and the film thicknesses of the second protection film 32 (Al₂O₃) made of Al₂O₃ are respectively 22 nm (region 1), 90 nm (region 2), 145 nm (region 3), 215 nm (region 4), and 265 nm (region 5) so that the initial reflectance is 12% in FIG. 7. In this regard, each of the regions 1-5 corresponds to an initial peak-to-peak range before crystallization of Al₂O₃.

As shown in FIGS. 9A-9E, in the regions 1, 2, 4, and 5, a stop of oscillation (rapid degradation) occurs due to a rapid increase of operating current; and in the regions 2 and 4, a rapid degradation occurs in some devices, and the operating-current change rates (ΔIop's) are high. On the contrary, in the region 3, it is shown that a rapid degradation does not occur. Note that all of the rapid degradations occur due to catastrophic optical damage of the cavity facets.

The cause of the rapid degradations occurred in the regions 1, 2, 4, and 5 shown in FIGS. 9A, 9B, 9D, and 9E will be discussed below.

First, the issue on oxygen diffusion will be described.

Oxygen diffusion is significantly reduced by using a c-axis oriented AlN film as the first protection film 31. However, since oxygen diffusion proceeds from the air through the second and the first protection films 32 and 31 to the cavity facet 30, each film thickness of the first and the second protection films 31 and 32 also has significant effect on oxygen diffusion. In the regions 1 and 2, the film thickness of the second protection film 32 is insufficient to prevent oxygen diffusion, and this is considered to cause the rapid degradation to occur on and near the cavity facet 30.

Next, the issue on stress will be described.

Since the AlN forming the first protection film 31 is a nitride, the AlN film has very high stress (tensile stress). It is known that only with the AlN film, this stress causes rapid degradation to occur on the cavity facet 30 in a short period of time. Therefore, it is indispensable to provide the second protection film 32. Here, in discussing the stress, if, for example, SiO₂ etc. having similar tensile stress to AlN is used, then rapid degradation still occurs on the cavity facet 30 because stress on the cavity facet 30 further increases. Meanwhile, as in the regions 4 and 5, if the second protection film 32 made of Al₂O₃ having compressive stress is deposited to a relatively large thickness, compressive stress becomes high. It is thought that this produces stress on the cavity facet 30, which causes the rapid degradation to occur as shown in FIGS. 9A, 9B, 9D, and 9E.

For these reasons, such a phenomenon is presumably caused by crystallization of the second protection film 32 made of Al₂O₃ during operation, during which oxygen diffusion is facilitated and stress is locally applied to the light-emitting region of the laminate structure 40. Thus, from a viewpoint of oxygen diffusion and stress, it can be understood that the film thickness of the second protection film 32 made of Al₂O₃ needs a restriction to ensure long-term reliability. Meanwhile, in the region 3 shown in FIG. 9C, the film thickness of the Al₂O₃ film is not limited to 145 nm when the reflectance is set within a range from 8% to 13%, and it has been verified that a good operating characteristic is similarly observed, thereby causing no rapid degradation.

Note that as can be seen from FIGS. 7 and 8, in the regions 2 and 4, the second reflectance Rf(n2) after prolonged operation is higher than the first reflectance Rf(n1) initially set, and easily reaches or exceeds 13%. This causes the optical density of the cavity facet 30 to increase and facilitates facet degradation. Accordingly, both the increase rate of operating current and the probability of occurrence of rapid degradation increase, and thus this trend is not preferable for ensuring reliability. On the contrary, in the region 3, the second reflectance Rf(n2) after prolonged operation shows a trend to be lower than the first reflectance Rf(n1) initially set.

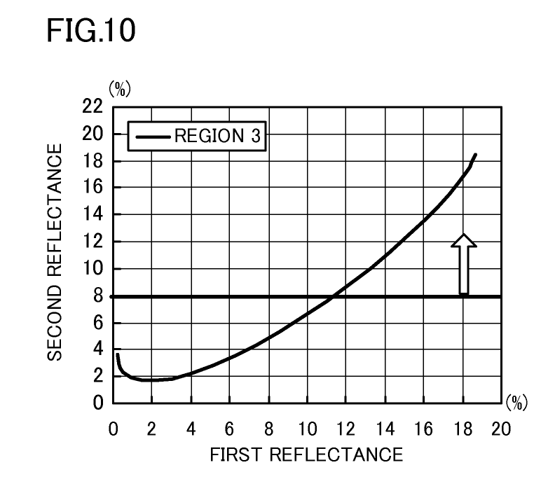

Furthermore, as shown in FIG. 10, if the first reflectance Rf(n1) is within a range from 11.5% to 13.0%, then the second reflectance Rf(n2) does not fall below 8%. Therefore, setting each of the film thicknesses of the AlN forming the first protection film 31 and the Al₂O₃ forming the second protection film 32 to a suitable value allows a reflectance within a range from 8% to 13% to be maintained over a long period of time. That is, setting the film thickness of the second protection film 32 to a value within the region 3 (λ/(2·n1)<t<3λ/(4·n1)) (where λ is the oscillation wavelength of laser light) is effective and preferable for ensuring long-term reliability for the semiconductor light-emitting device according to this embodiment.

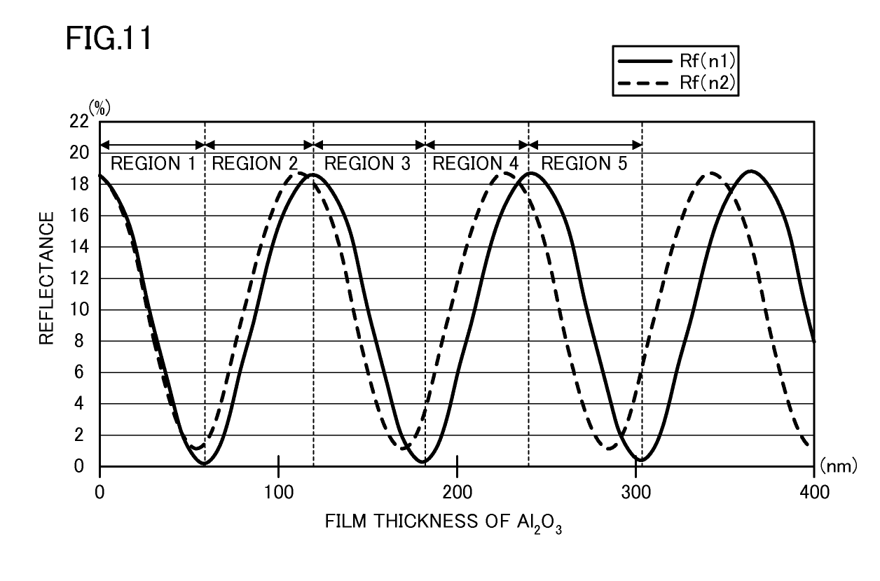

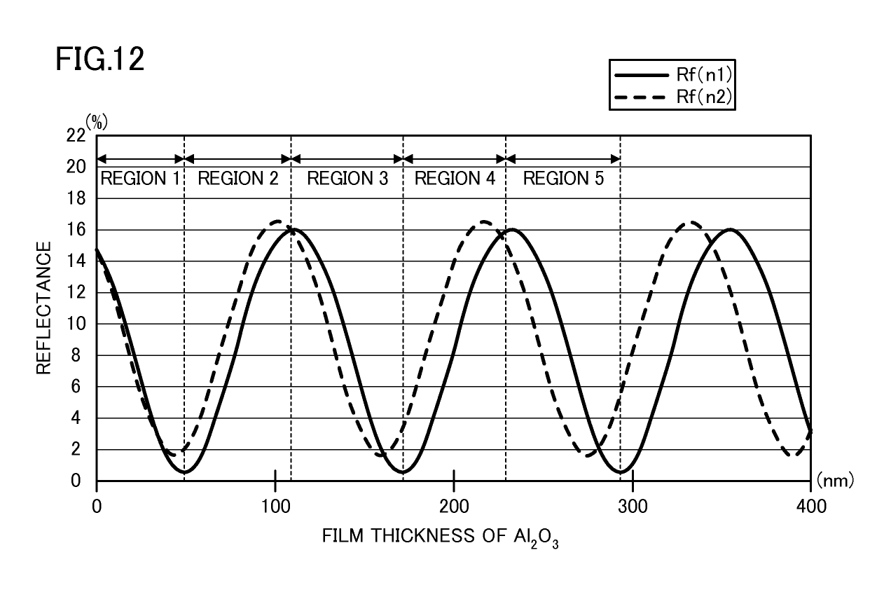

FIG. 11 illustrates a dependency of the reflectances of the cavity facet on the film thickness of the Al₂O₃ when the film thickness of the AlN forming the first protection film 31 is 4 nm. In addition, FIG. 12 illustrates a dependency of the reflectances of the cavity facet on the film thickness of the Al₂O₃ when the film thickness of the AlN forming the first protection film 31 is 20 nm. In both cases, the other conditions are similar to those of FIG. 7.

As can be seen from FIGS. 11 and 12, in both cases, the facet reflectances can satisfy a condition of greater than or equal to 8% and less than or equal to 13%, and in the region 3, the facet reflectances decrease if Al₂O₃ is crystallized.

As can be seen from FIG. 11, setting the film thicknesses of the AlN forming the first protection film 31 to 4 nm or more allows AlN to be crystal and Al₂O₃, which is easy to be crystallized, to be disposed apart from the cavity facet 30 having a high optical density, thereby allows crystallization of the first protection film 31 to be reduced. Furthermore, in this embodiment, only crystallization from the atmospheric side of the second protection film 32 needs to be considered, and thus setting the film thickness of the first protection film 31 to 4 nm or more and 20 nm or less provides similar advantages to the nitride semiconductor light-emitting devices shown in FIGS. 1 and 7.

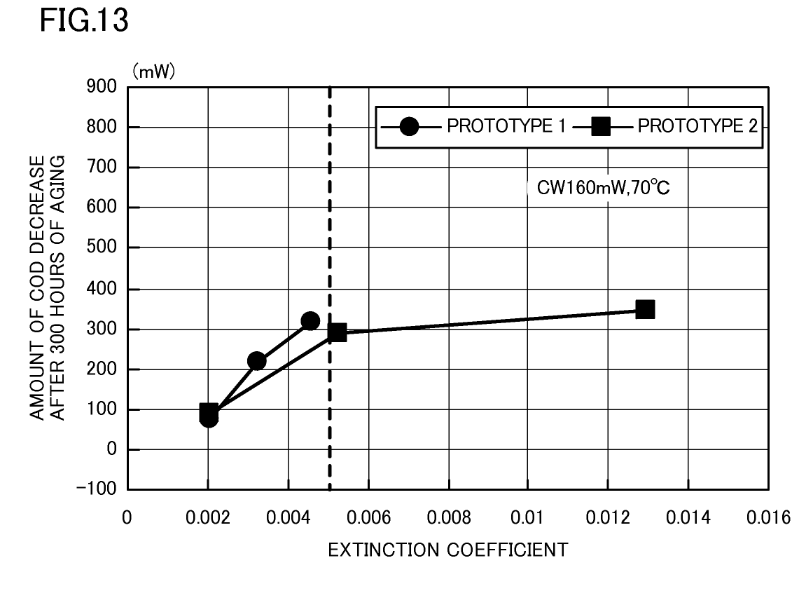

It is preferable that the extinction coefficient of the first protection film 31 made of AlN be 0.005 or less. Setting the extinction coefficient of the first protection film 31 to 0.005 or less allows light absorption in the light-permeated portion in the first protection film 31 to be reduced. As a result, as shown in FIG. 13, the decrease of COD level during laser operation can be reduced to 300 mW or less. Here, the laser operation condition is as follows: the temperature is 70° C., and the light output is 160 mW and is a continuously energized light-emission (CW) of 300 hours. In addition, the only difference between “Prototype 1” and “Prototype 2” is the extinction coefficient of the first protection film 31.

Next, the rear-facet-coating film (reflective film) on the reflecting-facet side will be described.

Similarly to the emitting-facet side, a cleaning process is performed before forming the reflective film provided on the reflecting facet of the cavity. Then, Ar gas and O₂ gas are introduced to the film deposition chamber 105 of the ECR system shown in FIG. 2, and an Al₂O₃ film, for example, is deposited as a first protection film. Following this, after the film deposition chamber 105 is modified, a reflective film made of a multi-layer film having six cycles of stacked SiO₂ and ZrO₂ films is formed, and the outermost surface is terminated with a ZrO₂ film. In this regard, each film thickness of the Al₂O₃ film, the SiO₂ films, and the ZrO₂ films is appropriately adjusted so that the reflectance with respect to the laser light is 90% or higher. Note that, even if Al₂O₃ in the reflective film on the reflecting-facet side is crystallized and therefore its refractive index changes, the reflectance for the laser light is hardly affected.

In addition, as shown in FIG. 3B, the configuration of the reflective film provided on the reflecting facet may include an AlN film as a third protection film 31A between the cavity facet (reflecting facet) and the Al₂O₃ film similarly to the front-facet-coating film. That is, the reflective film may be configured with the third protection film 31A made of AlN, a fourth protection film 32A made of Al₂O₃, a fifth protection film 33 made of a multi-layer film formed of stacked SiO₂ and ZrO₂ films, and a terminating film 34 terminated with SiO₂ on the outermost surface.

Thus, in the reflective film provided on the reflecting facet also, use of an AlN film as the third protection film 31A allows crystallization on the cavity-facet side of the Al₂O₃ film, which is the fourth protection film 32A, to be reduced. Furthermore, since oxygen permeation to the cavity facet can be reduced, degradation of the cavity facet occurring on the reflecting-facet side during laser operation can be prevented. In addition, providing the terminating film 34 made of SiO₂ on the outermost surface of the reflective film prevents crystallization at or near the atmospheric boundary which would be caused by the terminating film made of ZrO₂ having a low crystallization temperature as shown in Table 1 below, thereby allowing the light-emitting device to achieve a stable laser operation.

TABLE 1

| | Crystallization Temperature |
|---|---|
| Dielectric Film | Tc (° C.) |
| Nb₂O₅ | 500 |
| SiO₂ | ≧1000 |
| ZrO₂ | 400-800 |
| Al₂O₃ | 850 |

After this, a laser bar including a plurality of light-emitting devices receives a secondary cleavage into dice, and thus laser chips are obtained.

Next, a mounting process will be described. Each of the laser chips described below is firmly fixed on a submount made of, for example, aluminum nitride (AlN) or silicon carbide (SiC), on which solder material is arranged, and then is mounted on a stem. Then, wires made of gold (Au) for current supply are respectively connected to the p-side interconnect electrode 20 and to an interconnect electrode of the submount connected to the n-side contact electrode 21. Following this, a cap having a laser-light exit window is attached by fusion in order to isolate the laser chip from the ambient air, thus a nitride semiconductor light-emitting device is obtained.

An operation at room temperature of a nitride semiconductor light-emitting device achieved by this embodiment has shown that the threshold current value is 30 mA, the slope efficiency is 1.5 W/A, the oscillation wavelength is 405 nm, and a continuous oscillation occurs (or continuous wave (CW) is generated). In addition, a reliability test is performed with CW driving under a condition of high temperature and high power (70° C., 160 mW), and it has been shown that stable operation is possible over 1000 hours or longer.

An oscillation wavelength within a range from 395 nm to 420 nm is more preferable for a nitride semiconductor light-emitting device according to this embodiment.

In this way, in a semiconductor light-emitting device according to this embodiment, the protection film provided on each cavity facet has a stacked configuration of the first protection film 31 made of AlN and the second protection film 32 made of Al₂O₃; the film thickness “t” of the Al₂O₃ film, which is the second protection film 32, is set to satisfy λ/(2·n1)<t<3λ/(4·n1); and the facet reflectances on the emitting facet is set to satisfy Rf(n2)<Rf(n1) (where n1 is the initial refractive index, and n2 is the refractive index after crystallization). This significantly reduces oxidation and stress occurring at the boundary between the corresponding cavity facet and the first protection film 31 made of AlN, thereby can reduce facet degradation during laser operation. Thus, since reliability and durability of a light-emitting device can be greatly improved, high-power operation of 160 mW or higher, applicable to, for example, Blu-ray Disc on which dual layer recording can be performed at 4× or faster, can be performed.

As has been described, since the nitride semiconductor light-emitting device according to this embodiment can reduce oxidation and stress at the boundary between the cavity facet and the first protection film, and can reduce facet degradation, a facet protection film which can withstand a prolonged high-power laser operation can be achieved, and thus the present invention is useful for nitride semiconductor light-emitting devices such as light sources for optical pickups etc.

What is claimed is:

1. A nitride semiconductor light-emitting device, comprising:
a laminate structure formed of a plurality of nitride semiconductor layers including a light-emitting layer, and having cavity facets facing each other;
a first protection film made of aluminum nitride, formed over a light-emitting facet of the cavity facets; and
a second protection film made of aluminum oxide having a refractive index of n1, formed over the first protection film,
wherein
the second protection film has a crystallized surface at least in a region facing a light-emitting region on the cavity facets,
the thickness (t) of the second protection film satisfies λ/(2·n1)<t<3λ/(4·n1) (where λ is a wavelength of the output light), and
a second reflectance R(n2) (where n2 is a refractive index of the aluminum oxide which has been crystallized) of the light-emitting region in the cavity facets is lower than a first reflectance R(n1) of a region surrounding the light-emitting region in the cavity facets.

2. The nitride semiconductor light-emitting device of claim 1, wherein
the aluminum nitride forming the first protection film has an orientation where the crystal axis is different by 90° from the optical cavity facets.

3. The nitride semiconductor light-emitting device of claim 1, wherein
the first protection film has a film thickness of 4 nm or more and 20 nm or less.

4. The nitride semiconductor light-emitting device of claim 1, wherein
the extinction coefficient of the first protection film is 0.005 or less over a range of oscillation wavelength of the light emitted from the light-emitting layer.

5. The nitride semiconductor light-emitting device of claim 1, wherein
a reflectance of a facet-coating film formed of the first protection film and the second protection film is 8% or more and 13% or less.

6. The nitride semiconductor light-emitting device of claim 1, further comprising:
a third protection film formed over a light-reflecting facet opposite the light-emitting facet of the cavity facets, and having the same configuration as that of the first protection film; and
a fourth protection film formed over the third protection film, and having the same configuration as that of the second protection film.
